(19) United States
(12) Patent Application Publication
(10) Pub. No.: US 2026/0202768 A1
(43) Pub. Date: Jul. 16, 2026

(54) THERMAL REMOVER FOR METAL CLOGGING IN LITHOGRAPHY SYSTEMS

(71) Applicant: TAIWAN SEMICONDUCTOR MANUFACTURING COMPANY, LTD., Hsinchu (TW)

(72) Inventors: Jyun-Yan CHUANG, Hsinchu City (TW); Ming-Hsun TSAI, Hsinchu City (TW); Jia Hong CHEN, Taipei City (TW); Yi-Wen HU, New Taipei City (TW)

(73) Assignee: TAIWAN SEMICONDUCTOR MANUFACTURING COMPANY, LTD., Hsinchu (TW)

(21) Appl. No.: 19/024,342

(22) Filed: Jan. 16, 2025

(51) Int. Cl. G03F 7/00; B08B 7/00

(52) U.S. Cl. CPC G03F 7/70925; B08B 7/0071; G03F 7/70033; G03F 7/7085; G03F 7/7095; G03F 7/70983

(57) ABSTRACT

A method includes providing a thermal remover, wherein the thermal remover comprises a remover portion comprising a plurality of protrusions and a heater extending within the remover portion; positioning the remover portion in contact with a metal clogging deposited on an inner sidewall of a cover within a lithography system, wherein the inner sidewall comprises a plurality of vanes, wherein the protrusions are configured to conform to a shape of the vanes; heating the remover portion with the heater to melt the metal clogging; removing the melted metal clogging from the cover by withdrawing the remover portion.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a block diagram of a fabrication facility in accordance with some embodiments of the present disclosure.

FIG. 1B illustrates a schematic view of a lithography system in accordance with some embodiments of the present disclosure.

FIG. 1C illustrates a schematic view of an extreme ultraviolet (EUV) radiation source in accordance with some embodiments of the present disclosure.

FIGS. 2A-2D illustrate schematic diagrams of applying a thermal remover to different vanes in lithography systems in accordance with some embodiments of the present disclosure.

FIGS. 3A-3H illustrate schematic views of a thermal remover in accordance with some embodiments of the present disclosure.

FIGS. 4A-4D illustrate different thermal removers in accordance with some embodiments of the present disclosure.

FIGS. 5A-5C illustrate schematic views of intermediate stages of using the thermal remover to remove residue from the vane in the lithography system in accordance with some embodiments.

FIG. 6 is a flowchart of a method of using a thermal remover to remove residue from the vane in the lithography system in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

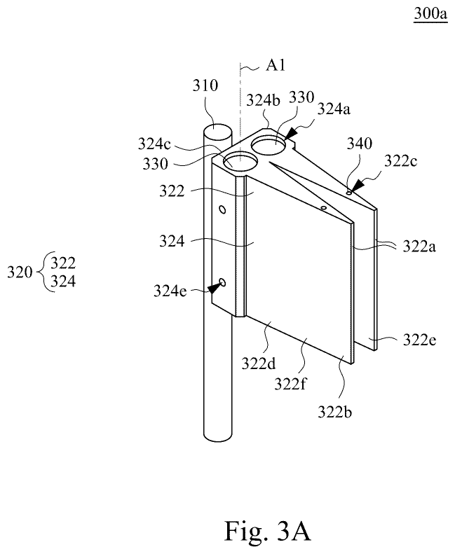

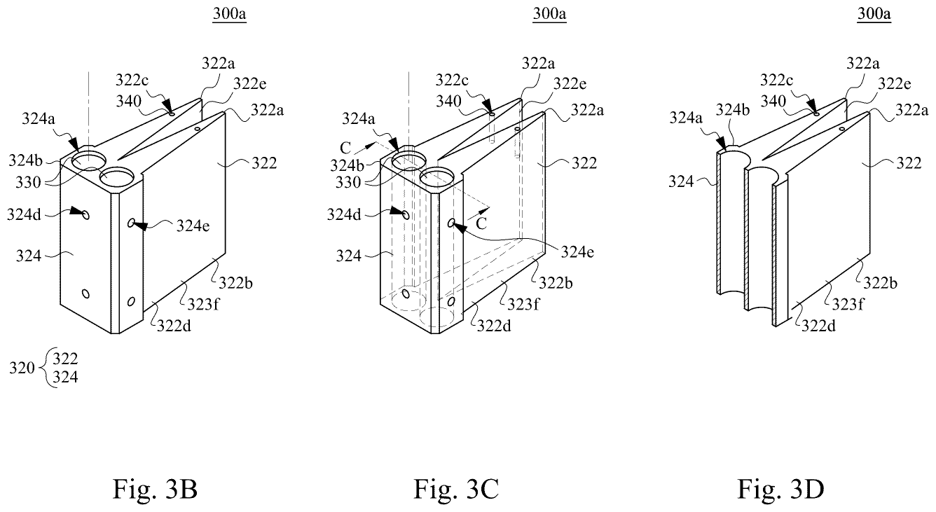

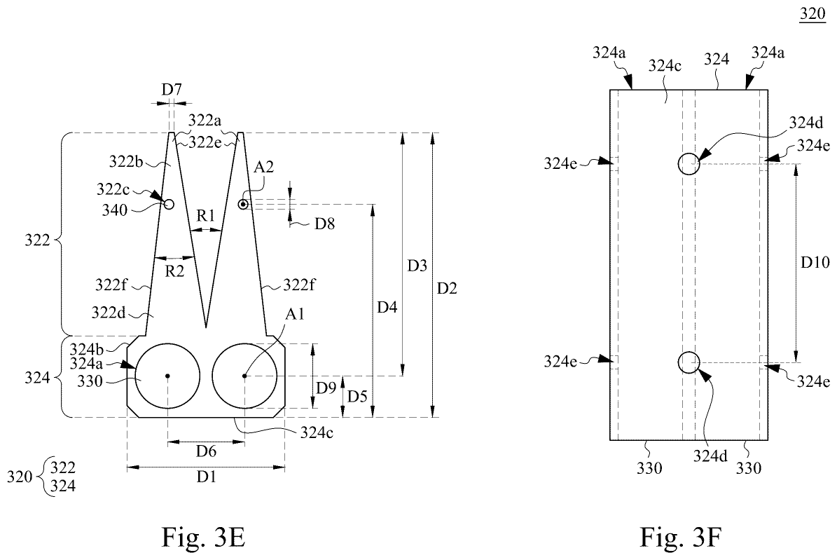

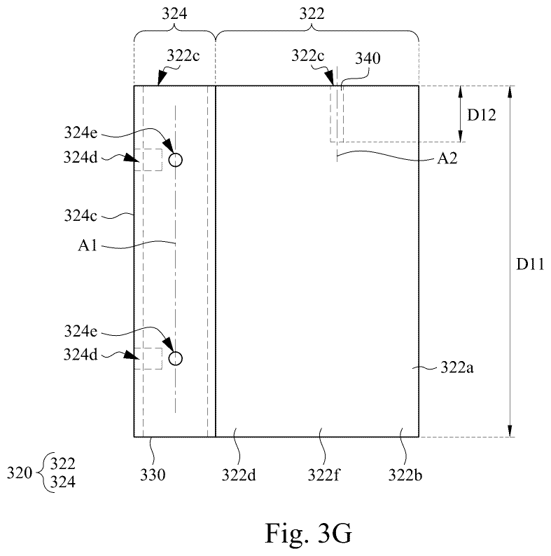

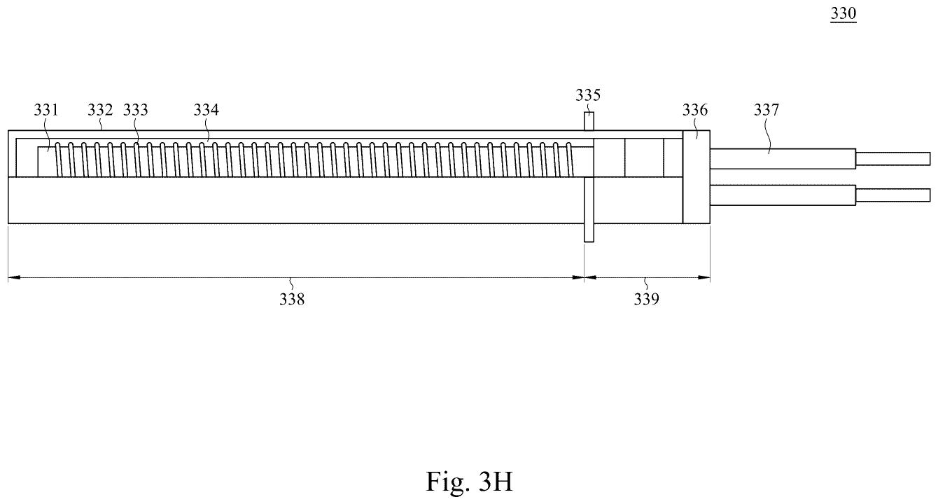

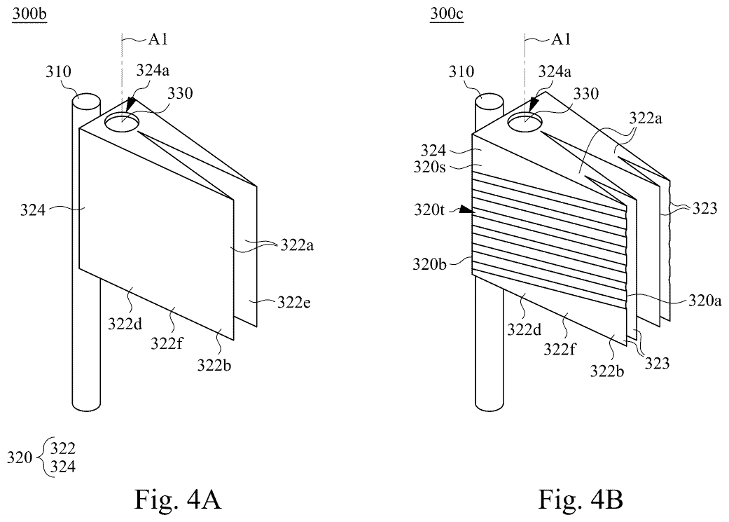

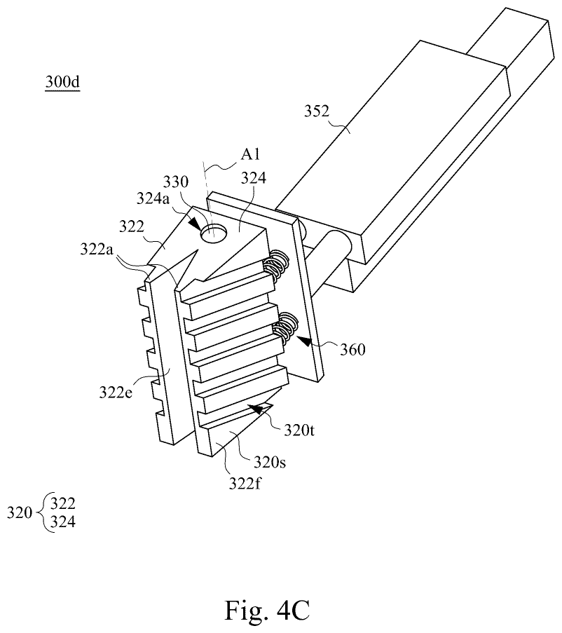

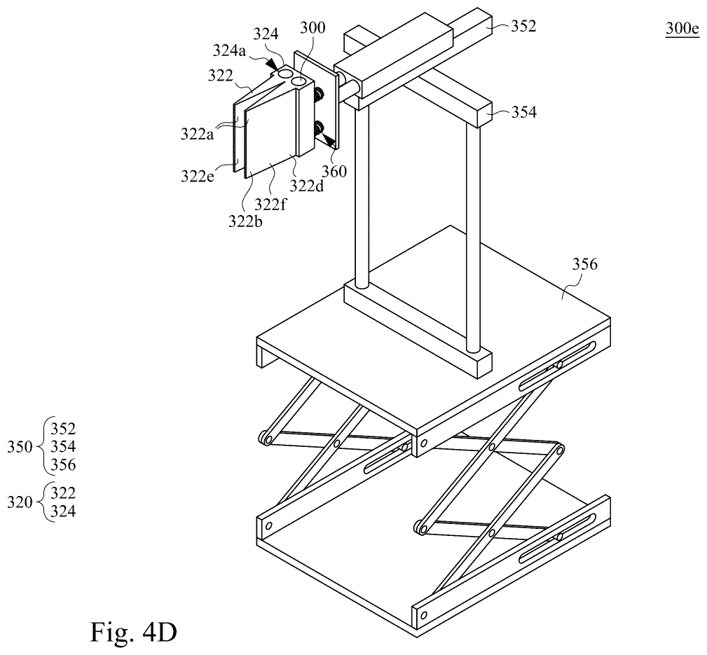

In some embodiments, metal clogging is an issue in a lithography system that uses liquid metal, such as those producing EUV light from liquid tin. Metal deposits on chamber walls of the lithography system can reduce tool efficiency and create operational challenges. Therefore, a thermal-based tool (e.g., thermal remover shown in FIGS. 3A-4D) is introduced to remove metal clogging from chamber walls of the lithography system. The thermal-based tool can be designed to conform to the shape of the chamber walls, ensuring efficient metal removal without power loss, improving operational efficiency in liquid metal applications, in lithography systems.

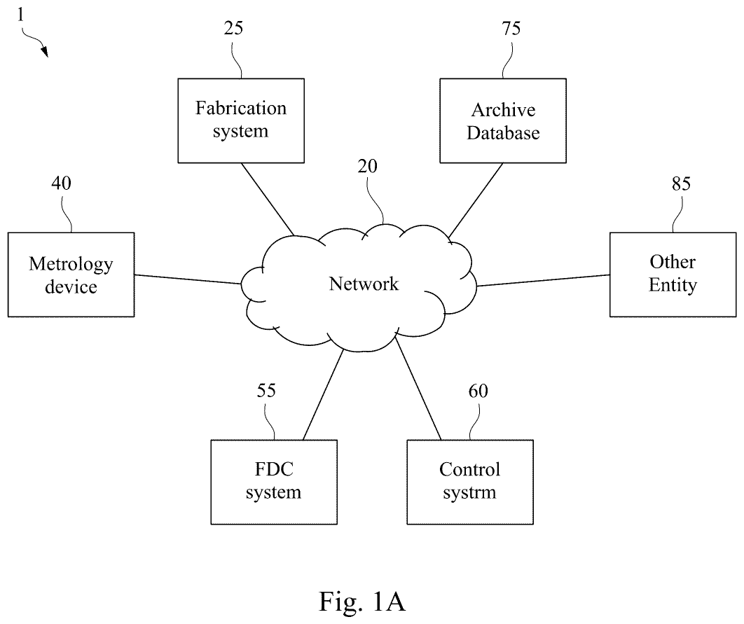

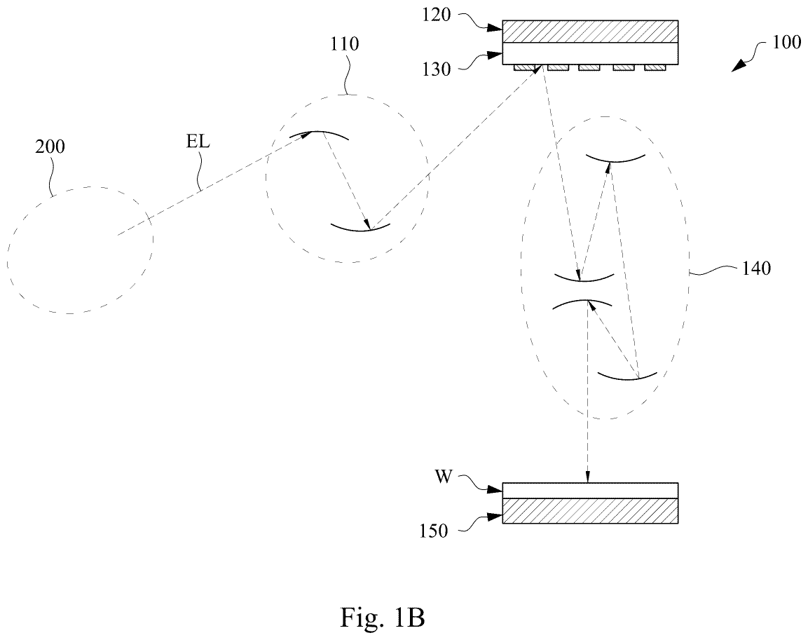

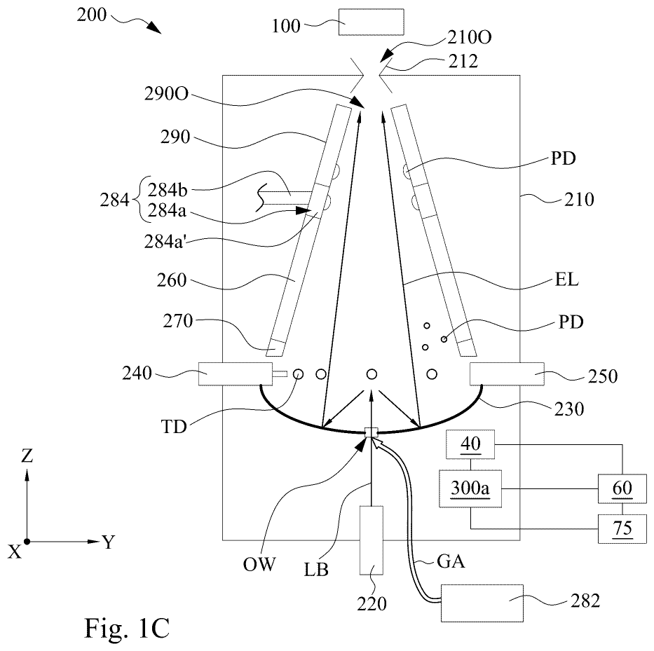

Reference is made to FIG. 1A. FIG. 1A is a block diagram of a fabrication facility in accordance with some embodiments of the present disclosure. The fabrication facility 1 implements integrated circuit manufacturing processes to fabricate integrated circuit devices. For example, the fabrication facility 1 may implement semiconductor manufacturing processes that fabricate semiconductor wafers. It should be noted that, in FIG. 1A, the fabrication facility 1 has been simplified for the sake of clarity to better understand the concepts of the present disclosure. Additional features can be added in the fabrication facility 1, and some of the features described below can be replaced or eliminated in other embodiments of the fabrication facility 1. The fabrication facility 1 may include more than one of each of the entities. In some embodiments, and may further include other entities not illustrated in the depicted embodiment. In some embodiments, the fabrication facility 1 can include a network 20 that enables various entities (a fabrication system 25 (e.g., lithography system 100 shown in FIG. 1B), a metrology device 40, a fault detection and classification (FDC) system 55, a control system 60, an archive data base 75, and another entity 85) to communicate with one another. The network 20 may be a single network or a variety of different networks, such as an intranet, the Internet, another network, or a combination thereof. The network 20 may include wired communication channels, wireless communication channels, or a combination thereof.

Reference is made to FIG. 1B. FIG. 1B illustrates a schematic view of a lithography system 100 in accordance with some embodiments of the present disclosure. The lithography system 100 may also be referred to as a scanner that is operable to perform lithography exposing processes with respective radiation source and exposure mode. In some embodiments, the lithography system 100 can be an extreme ultraviolet (EUV) lithography system designed to expose a resist layer by EUV light (or EUV radiation). The resist layer is a material sensitive to the EUV light. The EUV lithography system 100 can employ a radiation source 200 to generate EUV light EL, such as EUV light having a wavelength ranging between about 1 nm and about 100 nm. In certain examples, the EUV light EL has a wavelength range centered at about 13.5 nm. Accordingly, the radiation source 200 can be also referred to as an EUV radiation source 200. The EUV radiation source 200 may utilize a mechanism of laser-produced plasma (LPP) to generate the EUV radiation, which will be further described later.

The lithography system 100 can also employ an illuminator 110. In some embodiments, the illuminator 110 can include various reflective optics such as a single mirror or a mirror system having multiple mirrors in order to direct the EUV light EL from the radiation source 200 onto a mask stage 120, particularly to a mask 130 secured on the mask stage 120.

The lithography system 100 also can include the mask stage 120 configured to secure the mask 130. In some embodiments, the mask stage 120 can include an electrostatic chuck (e-chuck) used to secure the mask 130. In this context, the terms mask, photomask, and reticle are used interchangeably. In the present embodiments, the lithography system 100 can be an EUV lithography system, and the mask 130 can be a reflective mask. One exemplary structure of the mask 130 includes a substrate with a low thermal expansion material (LTEM). For example, the LTEM may include TiO₂ doped SiO₂, or other suitable materials with low thermal expansion. The mask 130 includes a reflective multi-layer deposited on the substrate. The reflective multi-layer can include plural film pairs, such as molybdenum-silicon (Mo/Si) film pairs (e.g., a layer of molybdenum above or below a layer of silicon in each film pair). Alternatively, the reflective multi-layer may include molybdenum-beryllium (Mo/Be) film pairs, or other suitable materials that are configurable to highly reflect the EUV light EL. The mask 130 may further include a capping layer, such as ruthenium (Ru), disposed on the reflective multi-layer for protection. The mask 18 can further include an absorption layer, such as a tantalum boron nitride (TaBN) layer, deposited over the reflective multi-layer. The absorption layer can be patterned to define a layer of an integrated circuit (IC). The mask 130 may have other structures or configurations in various embodiments.

The lithography system 100 also can include a projection optics module (or projection optics box (POB)) 140 for imaging the pattern of the mask 130 onto a semiconductor substrate W secured on a substrate stage (or wafer stage) 150 of the lithography system 100. The POB 140 can include reflective optics in the present embodiments. The light EL that is directed from the mask 130 and carries the image of the pattern defined on the mask 130 is collected by the POB 140. The illuminator 110 and the POB 140 may be collectively referred to as an optical module of the lithography system 100.

In the present embodiments, the semiconductor substrate W can be a semiconductor wafer, such as a silicon wafer or other type of wafer to be patterned. The semiconductor substrate W can be coated with a resist layer sensitive to the EUV light EL in the present embodiments. Various components including those described above can be integrated together and are operable to perform lithography exposing processes.

Reference is made to FIG. 1C. FIG. 1C illustrates a schematic view of an extreme ultraviolet (EUV) radiation source 200 in accordance with some embodiments of the present disclosure. In some embodiments, the EUV radiation source 200 can employ a laser produced plasma (LPP) mechanism to generate plasma and further generate EUV light from the plasma. The radiation source 200 can include a vessel 210, a laser source 220, a collector 230, a target droplet generator 240, a droplet catcher 250, a cover 260 (or cover), a gutter structure 270, a gas supply module 282, a gas exhaust module 284, and a cone structure 290. The space in the vessel 210 can be closed and maintained in a vacuum environment since the air absorbs the EUV radiation.

The target droplet generator 240 can deliver a target material TD into the space in the vessel 210 of the radiation source 200, in which the target material TD may be delivered in the form of liquid droplets, a liquid stream, solid particles or clusters, solid particles contained within liquid droplets or solid particles contained within a liquid stream. The target material TD can include suitable fuel material that has a radiation in the EUV range when being converted to a plasma state. For example, the target material TD may include water, tin, lithium, xenon, or the like. In some embodiments, the element tin can be pure tin (Sn); a tin compound, for example, SnBr₄, SnBr₂, SnH₄; a tin alloy, for example, tin-gallium alloys, tin-indium alloys, tin-indium-gallium alloys, or any other suitable tin-containing material.

The laser source 220 can be disposed at one end of the vessel 210. The laser source 220 may include a carbon dioxide (CO₂) laser source, a neodymium-doped yttrium aluminum garnet (Nd:YAG) laser source, or another suitable laser source to generate a laser beam LB. The laser beam LB vessel directed through an output window OW integrated with the collector 230. The output window OW can adopt a suitable material that is substantially transparent to the laser beam LB. The laser beam LB vessel directed to heating the target material TD, such as tin droplets, thereby generating high-temperature plasma which further produces the EUV light EL. The pulses of the laser source 220 and the droplet generating rate of the droplet generator 240 can be controlled to be synchronized, such that the target material TD receives peak power consistently from the laser pulses of the laser source 220. In some embodiments, the radiation source 200 may employ a dual LPP mechanism in which the laser source 220 is a cluster of multiple laser sources. For example, the laser source 220 may include a pre-heat laser source and a main laser source, which produce pre-heat laser beam and main laser beam, respectively. Each of the pre-heat laser source and the main laser source may be a CO₂ laser source, an Nd:YAG laser source, or another suitable laser source. The pre-heat laser beam can have a smaller spot size and less intensity than the main laser beam, and can be used for pre-heating the target material TD to create a low-density target plume, which is subsequently reheated by the main laser beam, generating increased emission of EUV light EL.

The EUV light EL can be collected by the collector 230 disposed in the vessel 210. The collector 230 further reflects and focuses the EUV light EL for the lithography exposure processes. The collector 230 can be designed with suitable coating material and shape, functioning as a mirror for EUV collection, reflection, and focus. In some examples, the collector 230 can be designed to have an ellipsoidal geometry. In some examples, the coating material of the collector 230 can be similar to the reflective multilayer of the EUV mask 130 (referring to FIG. 1B). In some examples, the coating material of the collector 230 includes a reflective multi-layer (such as a plurality of Mo/Si film pairs) and may further include a capping layer (such as Ru) coated on the reflective multi-layer to substantially reflect the EUV light. In some examples, the collector 230 may further include a grating structure designed to effectively scatter the laser beam directed onto the collector 230. For example, a silicon nitride layer may be coated on the collector 230 and patterned to have a grating structure.

In some embodiments, the laser beam LB may or may not hit every droplet of the target material TD. For example, some droplets of the target material TD may be purposely missed by the laser beam LB. In the present embodiments, the droplet catcher 250 can be installed opposite the target droplet generator 240 and in the direction of the movement of the droplet of the target material TD. The droplet catcher 250 can be configured to catch any droplets of the target material TD that are missed by the laser beam LB.

The radiation source 200 may further include an intermediate focus (IF) unit 212 included within an exit aperture 2100 of the EUV source vessel 210, in which the intermediate focus unit 212 is configured to provide intermediate focus to the EUV radiation EL. The collector 230 can focus the EUV light EL generated by the plasma toward the intermediate focus unit 212. The intermediate focus unit 212 can be located between the EUV source vessel 210 and the scanner (i.e., the lithography system 100) including optical elements configured to direct the EUV light EL to a workpiece (e.g., a semiconductor substrate). In some embodiments, the intermediate focus unit 212 may comprise a cone shaped aperture configured to provide for separation of pressures between the EUV source vessel 210 and the scanner (i.e., the lithography system 100). In some embodiments, the intermediate focus unit 212 may extend into the scanner (i.e., the lithography system 100).

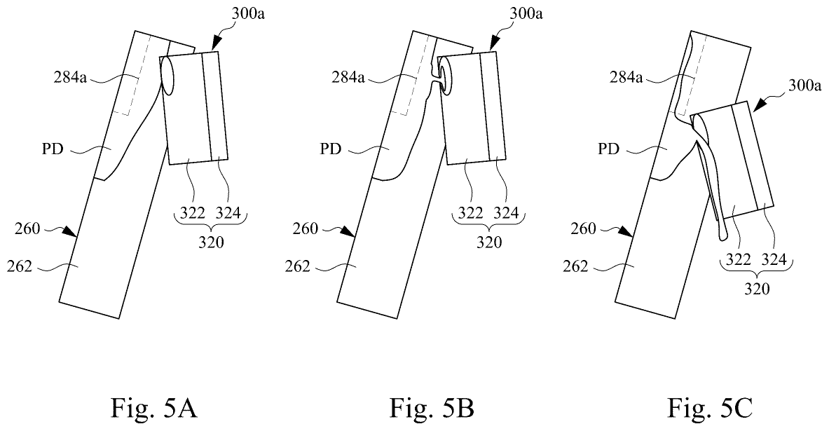

In some embodiments, the high-temperature plasma may cool down and become vapors or small particles, which may be collectively referred to as debris PD. The debris PD (see FIGS. 5A-5C) may deposit onto the surface of the collector 230, thereby causing contamination thereon. Over time, the reflectivity of the collector 230 degrades due to debris accumulation and other factors such as ion damages, oxidation, and blistering.

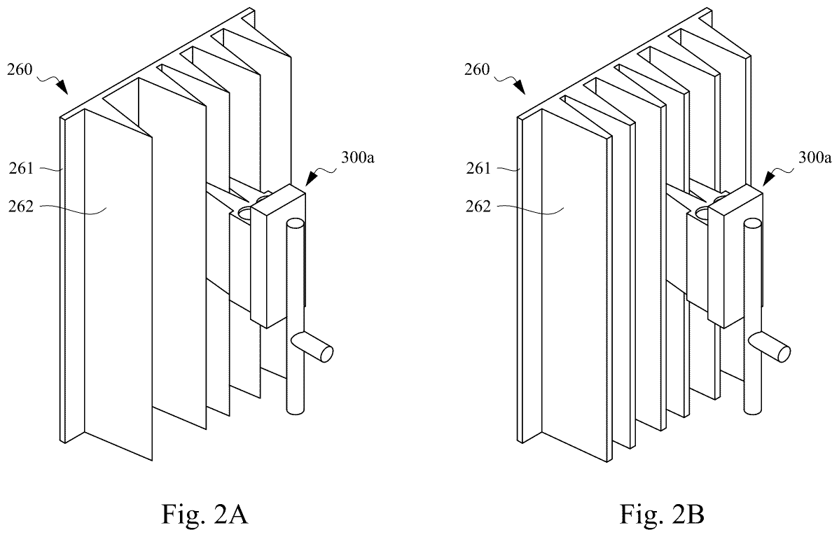

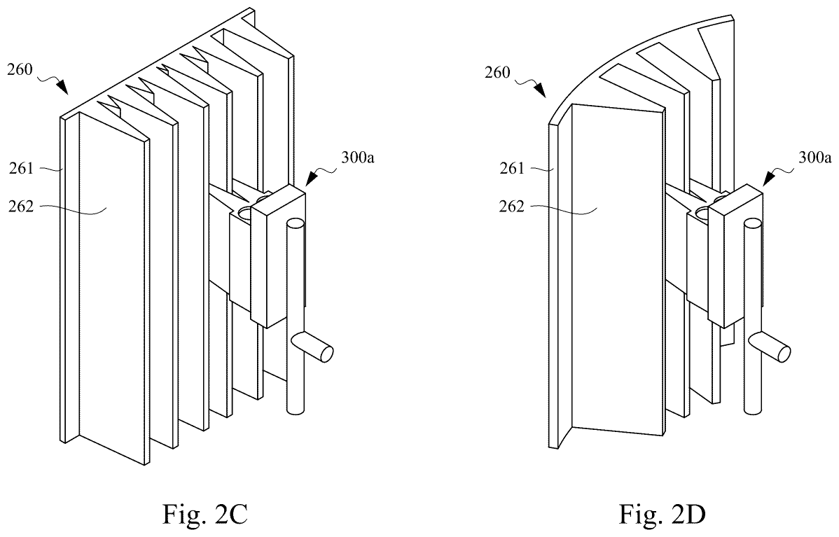

The cover 260 can surround the vessel 210 for ventilation and for collecting debris PD (see FIGS. 5A-5C). In some embodiments, the cover 260 can be made of a suitable solid material, such as stainless steel. The cover 260 can be designed and disposed around the collector 230. In some embodiments, the cover 260 may include a baffle assembly, such as plural vanes 262, which is illustrated in FIGS. 2A-2D. When the debris PD vapor comes in contact with the cover 260 (e.g., the baffle assembly), it may condense into a liquid form and flow into a lower section of the cover 260 due to gravity. The lower section of the cover 260 may provide holes (not shown) for draining the liquid debris PD out of the cover 260. For example, the lower section of the cover 260 may be connected to the gutter structure 270 which may be connected to a fuel container 400 (referring to FIG. 2B). Through this configuration, the liquid debris PD flows along and/or within the cover 260 (e.g., the baffle assembly) and is received in the gutter structure 270, from which it flows into a fuel container (not shown). In some embodiments, the radiation source 200 can further include a heating unit disposed around a portion of the cover 260. The heating unit can function to maintain the temperature inside the cover 260 above a melting point of the debris PD, thereby preventing the debris PD to be solidified on the inner surface of the cover 260.

In some embodiments, the radiation source 200 can further include various pipelines for integrating the gas supply module 282 with the collector 230. The gas supply module 282 can be configured to provide gas GA into the vessel 210 and particularly into a space proximate to the reflective surface of the collector 230. In some embodiments, the gas GA is hydrogen gas, which has less absorption to the EUV radiation. When the target material TD contains tin, hydrogen gas GA reaching to the coating surface of the collector 230 (and the output window OW as well) reacts chemically with tin to form stannane (SnH₄), a gaseous byproduct of the EUV generation process itself. Stannane can be then pumped out and discarded. The gas GA is provided for various protection functions, which include effectively protecting the collector 230 from the contaminations by tin particles. Other suitable gas may be alternatively or additionally used. The gas GA may be introduced into the collector 230 through openings (or gaps) near the output window OW through one or more gas pipelines. In some embodiments, the debris PD may include such byproducts between the residues of the target material TD and the gas GA. In some embodiments, the cover 260 and the collector 230 has a certain gap therebetween, and the gap also can function as a gas flow path for providing gas GA into the collector 230 and the cover 260. In some embodiments, the cone structure 290 can have an opening 290O allowing the EUV light EL to pass through itself at its narrow top section, and in some embodiments, the gas GA may be introduced from the opening 290O of the cone structure 290.

The gas GA may also function to carry the debris PD away from the collector 230 and the cover 260 and into the gas exhaust module 284. In some embodiments, the gas exhaust module 284 can include a gas outlet structure 284a connected to one or more pumps (not shown) through one or more exhaust lines 284b. The pump can draw airflow from the cover 260 into the exhaust line 284b for effectively pumping out the debris PD. At this point, the gas GA and the debris PD may be collectively referred to as the exhaust of the radiation source 200. In some embodiments, the cover 260 can be designed to have a cone shape with its wide base integrated with the collector 230 and its narrow top section facing the scanner (i.e., the lithography system 100), and the gas exhaust module 284 may be connected to the cover 260 at its narrow top section. Installing the gas exhaust module 284 at the top section of the cover 260 can help the removal of the remaining portion of the debris PD from the space defined by the collector 230 and the cover 260. In some embodiments, the gas exhaust module 284 may include a scrubber 284a′ disposed at the entrance of the exhaust line 284b (e.g., adjacent to or on the gas outlet structure 284a) for stopping the debris PD from getting into the exhaust line 284b. That is, the scrubber 284a′ may scrub gas vapors or dilute the exiting gas before the gas is released into the surroundings.

Reference is made to FIGS. 2A-2D. FIGS. 2A-2D illustrate schematic diagrams of applying a thermal remover 300a to different covers (e.g., cover 260) in lithography systems in accordance with some embodiments of the present disclosure. While FIGS. 2A-2D illustrate embodiments of applying the thermal remover 300a to different covers in lithography systems, the present disclosure may repeat reference numerals and/or letters in the various examples. This repetition is for simplicity and clarity and does not dictate a relationship between the various embodiments and/or configurations discussed.

In some embodiments, debris PD may solidify on the inner surface of cover 260, potentially blocking the gas exhaust module 284 and negatively impacting the process. To address this issue, the thermal remover 300a has been developed to effectively remove the debris PD from the cover 260, ensuring smooth operation of the system. The thermal-based tool (e.g., thermal remover 300a) can be designed to conform to the shape of the chamber walls, providing efficient contact and effective debris removal. The adaptability of the tool to various chamber geometries can achieve thorough cleaning without power loss or operational inefficiency.

As shown in FIGS. 2A-2D, the cover 260 can include side wall 261 and multiple vanes 262, which are installed on the inner surface of side wall 261 and extend towards the interior of cover 260. In some embodiments, the side wall 261 of the cover 260 may also vary in geometry. In some embodiments, at least a portion of side wall 261 can be flat (see FIGS. 2A, 2B, and 2C), allowing for installation of vanes 262 and effective coverage of the chamber surface. In some embodiments, at least a portion of the side wall 261 can be curved (see FIG. 2D), with the vanes 262 radially arranged on the curved surface, allows for better distribution of heat and improves the overall efficiency of the debris removal process.

The vanes 262 can guide and direct the flow of heat. In some embodiments, as shown in FIG. 1C, the vane 262 can extend along the Z-direction, protruding towards the interior of the cover 260 to improve heat transfer efficiency, ensuring that the debris PD can be fully exposed to the heat source, facilitating efficient melting and removal. In some embodiments, the shape of the vane 262 may gradually narrows away from the side wall 261, forming either a triangular cross-section (see FIGS. 2A and 2C) or a trapezoidal cross-section (see FIGS. 2B, 2C, and 2D). These cross-sectional designs can be chosen to maximize the contact area and enhance the transfer of thermal energy to the debris. In some embodiments, the vanes 262 can be evenly spaced on the side wall 261 (see FIGS. 2B and 2D), ensuring uniform heat distribution and consistent debris removal. In some embodiments, the vanes 262 may be unevenly spaced on the side wall 261 (see FIG. 2A), allowing for targeted cleaning in areas where debris accumulation is more severe. Additionally, in some embodiments, the size of adjacent vanes 262 may differ (see FIG. 2A), enabling the tool to address varying levels of debris buildup effectively.

The thermal remover 300a can be versatile and can be applied to different shapes of the cover 260 to remove debris PD effectively. Its ability to adapt to various geometries can ensures that it can handle a wide range of clogging scenarios, making it a tool for maintaining the efficiency of liquid metal systems. Detailed information on the thermal remover 300a, including its structure and operation, can be found in FIGS. 3A-5C.

Reference is made to FIGS. 3A-3H. FIGS. 3A-3H illustrate schematic views of the thermal remover 300a in accordance with some embodiments of the present disclosure. FIG. 3A illustrates a schematic perspective view of the thermal remover 300a in accordance with some embodiments of the present disclosure. FIGS. 3B and 3C illustrate schematic perspective views of a remover portion 320 of the thermal remover 300a in accordance with some embodiments of the present disclosure. FIG. 3D illustrates a schematic analytical view obtained from reference cross-sections C1-C1′ in FIG. 3B. FIGS. 3E, 3F, and 3G illustrate different schematic side views of the remover portion 320 in the thermal remover 300a in accordance with some embodiments of the present disclosure. FIG. 3A illustrates a schematic perspective view of a heater 330 in the thermal remover 300a in accordance with some embodiments of the present disclosure. As shown in FIGS. 3A-3H, the thermal remover 300a can address the issue of metal clogging by efficiently removing debris from chamber surfaces. In some embodiments, the metal clogging can be the debris PD. The thermal remover 300a can include of several components that work in concert to achieve effective debris removal: a support part 310, a remover portion 320 connected to the support part 310, a heater 330 extending within the remover portion 320, and a temperature sensor 340 extending within the remover portion 320.

In some embodiments, the support part 310 can provides structural stability to the thermal remover 300a and serve as the connection between the remover portion 320 and the larger assembly. The support part 310 can maintain the positioning of the remover portion 320 during the cleaning process, ensuring that the thermal remover can be properly aligned with the debris to be removed.

In some embodiments, the remover portion 320 can be an active cleaning component of the thermal remover 300a. The remover portion 320 can include of a body part 322 and a heating part 324. In some embodiments, the remover portion 320 can be interchangeable referred to as a thermal-based knife. The remover portion 320 can be responsible for directly contacting the debris PD (see FIGS. 5A-5C) and delivering sufficient heat to melt and dislodge the debris PD. The body part 322 can be used to contact and melt the debris PD deposited on cover 260 (see FIGS. 4A-4D). The body part 322 can ensure effective heat transfer and debris PD removal. The body part 322 can protrude from the heating part 324, allowing it to extend deeper into the chamber where the debris PD is located. In some embodiments, the body part 322 can include at least one protrusion 322a.

To achieve improved thermal contact, the geometry of the remover portion 320, particularly the protrusion 322a, can have a specific shape to facilitate depth removal. The protrusion 322a can ensure that the remover portion 320 can penetrate the debris effectively, maximizing the surface contact area and ensuring that the heat is concentrated where it is needed most. The protrusion 322a can be capable of penetrating even deeply seated clogging, thereby enhancing the de-clogging efficiency. In some embodiments, protrusion 322a can gradually narrow away from the heating part 324. This narrowing shape can enhance the precision of the thermal remover and ensure better contact with the debris PD. As shown in FIGS. 3A-3E, the body part 322 may have two protrusions 322a, though this number is not limiting, and other configurations may be employed. The protrusions 322a may have a triangular (e.g., V-shape) or trapezoidal cross-section to conform to the shape of the chamber walls, ensuring maximum contact and efficient heat transfer. The cross-sectional shape can be selected to optimize the thermal contact area and provide effective coverage of the chamber wall surface. In some embodiments, the body part 322 may be configured as a triangular prism or a trapezoidal prism.

In some embodiment the cross-sectional area of the body part 322 of the remover portion 320 can be maximized, such that the heat transfer rate can be increased, enabling efficient and rapid melting of the tin clogging. The large cross-section can provide a greater area for heat conduction, contributing to the overall effectiveness of the thermal remover 320. Specifically, as shown in FIG. 3E, a cross-sectional view obtained from a reference cross-section perpendicular to a lengthwise direction of the heater 330 can illustrate the dimensions of the body part 322. The cross-sectional area of the body part 322 can range from about 2000 to 6000 mm², such as approximately 2000, 3000, 4000, 4800, 5000, or 6000 mm². This range of cross-sectional areas can provide flexibility in adapting the thermal remover 300a to various clogging scenarios, ensuring that the remover can effectively cover different levels of clogging while maintaining efficient heat transfer.

As shown in FIG. 3E, in some embodiments, the remover portion 320 can have specific dimensions to ensure that it can perform metal de-clogging effectively. The remover portion 320 includes two dimensions D1 and D2. The dimension D1 can represent the length extending in the arrangement direction of the protrusions 322a, ensuring that the remover portion can be effectively positioned to apply heat across the entire length of the clogging, allowing for uniform heat application. In some embodiments, the dimension D1 can range from approximately 30 to 70 mm, such as 30, 35, 40, 45, 48.8, 50, 55, 60, 65, or 70 mm. The dimension D2 can represent the length extending in a direction perpendicular to the arrangement direction of the protrusions 322a. In some embodiments, the dimension D2 can be greater than D1, providing a broader contact area for effective debris removal. In some embodiments, the dimension D2 can range from approximately 70 to 120 mm, with possible values such as 70, 75, 80, 85, 90, 95, 100, 105, 110, 115, or 120 mm.

In some embodiments, the protrusions 322a can have a non-smooth inner surface 322e to enhance the de-clogging process. Specifically, the textured or uneven surface can provide additional mechanical grip on the metal debris, making it easier to dislodge during the melting phase. The non-smooth inner surface 322e can help in breaking up the debris more effectively by providing multiple points of contact, which can be useful when dealing with stubborn clogging that resists removal, allowing for better mixing of the melted debris, reducing the likelihood of residue remaining after the removal process. Additionally, the inner surface 322e of protrusion 322a can be rougher than the outer surface 322f, providing an improved grip on the debris, enhancing the contact and ensuring that the debris can be effectively removed, while the smoother outer surface reduces resistance when moving within the chamber.

The heating part 324 can be integral to the remover portion 320, as it generates and delivers the heat to melt the debris. The heating part 324 can have at least one accommodating portion 322a to house the heater 330. The heater 330, positioned within the heating part 324, produces thermal energy that is then transferred to the body part 322, enabling the removal of the debris PD (see FIGS. 5A-5C). In some embodiments, the heating part 324 may have a rectangular cross-section with chamfers 324b, which serves to reduce stress concentration and improve the durability of the component. The heating part 324 may also be a rectangular or trapezoidal prism. This flexibility in shape can allow the heating part 324 to adapt to different chamber configurations and ensures proper fit and heat distribution.

The heater 330 can provide the thermal energy to melt the metal debris PD (see FIGS. 5A-5C). The heater 330 can extend within the heating part 324 and can be housed in an accommodating portion 324a of the heating part 324. In some embodiments, the accommodating portion 324a can be a circular elongated hole extending through the heating part 324, providing a secure housing for the heater 330, ensuring that the heat generated by the heater is efficiently transferred to the body part 322 and, subsequently, to the debris PD. In some embodiment, multiple heaters 330 (e.g., dual heaters) can be used in the thermal remover 300a. The use of dual heaters 330 in the thermal remover 300a can provide a more balanced and consistent heat distribution, such that the thermal gradient can be minimized, allowing for uniform heating across the entire remover portion 320. This uniformity can melt metal debris evenly, avoiding hotspots or insufficiently heated areas. As shown FIG. 3H, the heater 330 can include several components (e.g., core 331, sheath 332, resistance wire 333, metal oxide (e.g., magnesium oxide, MgO) insulation 334, flange 335, seal 336, lead wire 337, heating part 338, and non-heating part 339), each contributing to its effectiveness in delivering and controlling the thermal energy.

In some embodiments, the core 331 can form the central part of the heater 330. It can serve as the main support for other components, ensuring the heater 330 can maintain its structural integrity during operation. In some embodiments, the sheath 332 can surround the core 331, which acts as a protective casing for the internal components. The sheath 332 can be made of a material that can tolerate high temperatures while protecting the internal resistance wire and insulation. The sheath 332 can help prevent oxidation or damage due to exposure to external environments. In some embodiments, the resistance wire 333 can be the main heating element within the heater 330. The resistance wire 333 can be wound around the core 331 and can be designed to generate heat when an electric current passes through it. The material of the resistance wire 333 can have high resistance and improved heat-generating properties. The length and configuration of the resistance wire 333 can be optimized to produce the desired temperature for melting metal clogging, ensuring efficient energy conversion. In some embodiments, the metal oxide (e.g., magnesium oxide, MgO) insulation 334 can be used as an insulating material between the resistance wire 333 and the sheath 332. The metal oxide insulation 334 can prevent the resistance wire 333 from making direct contact with the sheath 332, thus preventing short circuits while ensuring safety and reliability.

In some embodiments, the flange 335 can be used to secure the heater 330 in place. The flange 335 can help in mounting the heater 330 within the thermal remover 300a, ensuring that it remains properly positioned during operation. The flange 335 also can act as a boundary between the heating part 338 and the non-heating part 339 of the heater 330, aiding in installation and stability. In some embodiments, the seal 336 can be located near the non-heating part 339 of the heater 330 to prevent moisture and contaminants from entering the internal part of the heater 330. The seal 336 can ensure the heater 330 remains protected, extending its operational life and maintaining consistent performance. In some embodiments, the lead wires 337 can extend from the non-heating part 339 of the heater 330. The lead wires 337 can provide the electrical connection required for powering the resistance wire 333. The lead wires 337 can handle high current loads and be well insulated to ensure safety. The lead wires 337 can connect the heater 330 to the external power source, enabling precise control of the heating element.

In some embodiments, the heating part 338 of the heater 330 can be the main body of heater 330, which contains the resistance wire 333 and the metal oxide insulation 334. The heating part 338 can be responsible for generating and transferring heat to the surrounding materials, enabling effective melting of metal clogging. The non-heating part 339 of the heater 330 can include the flange 335, the seal 336, and the lead wires 337. The non-heating part 339 can remain cooler compared to the heating part 338, allowing for safe handling and mounting of the heater 330.

The heater 330 can provide consistent and efficient thermal energy required for metal de-clogging. The arrangement of components, such as the resistance wire 333 and metal oxide insulation 334, can ensure that the generated heat can be uniformly distributed, allowing the thermal remover to effectively reach and maintain the required temperatures. The sheath 332 and sealing mechanisms can help protect the internal components, allowing for reliable and long-lasting operation. The lead wires 337 can connect the heater 330 to the power supply, allowing for temperature control to manage the melting process of metal clogging. By using a combination of materials for insulation and resistance, the heater 330 can be able to achieve the precise thermal output for the efficient operation of the thermal remover 300a. The flange 335 can allow for installation into the thermal remover setup, while the separation between the heating part 338 and the non-heating part 339 can ensure that the components can operate safely without overheating.

As shown in FIGS. 3A-3G, in some embodiments, to ensure accurate control of the temperature during the de-clogging process, the temperature sensor 340 can be provided. The temperature sensor 340 can maintain thermal conditions within the remover portion 320, ensuring that the required temperature for melting debris is consistently achieved and maintained. The temperature sensor 340 can extend within the protrusion 322a and be housed in an accommodating portion 322c, allowing for direct monitoring of the temperature at locations, providing real-time data that can help maintain the conditions for effective de-clogging. In some embodiments, the accommodating portion 322c can extend into the protrusion 322a to position the temperature sensor 340 as close as possible to the debris being melted, ensuring that the temperature readings can reflect the actual conditions where the thermal energy is applied.

The accommodating portion 322c can be a circular elongated hole extending through the heating part 324 and have a central axis A2 (see FIG. 3E) positioned in parallel with a central axis A1 (see FIG. 3E) of the accommodating portion 324a, allowing the temperature sensor 340 to be aligned with the heating element (e.g., heater 330), which in turn ensures consistent and accurate readings. In some embodiments, the accommodating portion 322c can have a smaller cross-sectional area compared to the accommodating portion 324a, ensuring a snug fit for the temperature sensor 340 and improving the accuracy of the temperature readings by minimizing movement and enhancing the sensor's contact with the surrounding material. In some embodiments, multiple temperature sensors 340, such as dual sensors, can be used within the thermal remover 300a. In some embodiments, multiple temperature sensors 340 can be placed at different positions within the remover portion 320, such as near a base 322d and a tip 322b of the protrusion 322a, allowing for a more comprehensive temperature profile, enabling better control over the heating process and ensuring that the entire remover portion is consistently within the temperature range.

In some embodiments, specific dimensions can be defined to optimize the effectiveness of the thermal remover 300a. These dimensions can help determine the placement of different components within the thermal remover 300a, ensuring that the heat is applied effectively and the entire remover portion 300 is stable during operation. As shown in FIG. 3E, a distance D3 can be measured from the center axis A1 of the accommodating portion 324a to the tip 322b of the protrusion 322a. In some embodiments, the distance D3 can be greater than the maximum dimension of the vane 262. This can ensure that the protrusion 322a can extend sufficiently beyond the vane 262 to provide effective contact with the metal clogging, facilitating more efficient heat application. The maximum dimension of the vane 262 (see FIGS. 2A-2D) can be in a range from about 60 to 100 mm, such as 50, 60, 70, 77.5, 80, 90, or 100 mm. The distance D3 from the center axis A1 of the accommodating portion 324a to the tip 322b of the protrusion 322a can also be in a range from approximately 60 to 100 mm, such as 60, 68, 70, 80, 90, or 100 mm, ensuring that D3 can be greater than the maximum dimension of the vane 262 can allow the thermal remover 300a to reach deeper clogs effectively.

In FIG. 3E, a distance D4 can be defined as the distance from the center axis A2 of the accommodating portion 322c to a sidewall 324c of the heating part 324 that faces away from the protrusion 322a. The distance D4 can allow for efficient heat distribution without risk of overheating or inadequate contact. The distance D4 can range from approximately 50 to 90 mm, such as 50, 55, 60, 65, 68, 70, 75, 80, 85, or 90 mm. A distance D5 can be measured from the center axis A1 of the accommodating portion 324a to the sidewall 324c of the heating part 324. The distance D5 can defines the placement of the heater 330 within the heating part, ensuring that there is sufficient space for optimal heat conduction without excess dissipation. The distance D5 can range from approximately 5 to 25 mm, such as 5, 10, 12.5, 15, 20, or 25 mm. In some embodiments, a distance between the center axes A1 of the accommodating portion 324a can be substantially the same as a distance between the center axes A1 of the accommodating portion 322c, and this distance can be defined as the distance D6. In some embodiments, the distance D6 can be in a range from approximately 15 to 35 mm, such as 15, 20, 24.4, 25, 30, or 35 mm. This alignment can ensure that the heating part 324 and the body part 322 of the remover portion 320 can be aligned for optimal heat transfer and stability, thereby improving the overall performance of the thermal remover.

In FIG. 3E, the tip 322b of the protrusion 322a can have a width D7 that is smaller than the width of the base 322d of the protrusion 322a. This tapering design can allow the protrusion to focus heat and pressure effectively at the tip 322b, enhancing the penetration and removal capability of the remover. In some embodiments, the width D7 of the tip 322b can be in a range from approximately 1 to 5 mm, such as 1, 2, 3, 4, or 5 mm. In some embodiment, the narrower tip 322b can help concentrate the thermal energy, making it more effective in breaking through and melting metal clogging, while the broader base provides structural stability and support.

In FIG. 3E, a maximum dimension D8 (or diameter) of the accommodating portion 322c of the body part 322 can be smaller than a maximum dimension D9 (or diameter) of the accommodating portion 324a of the heating part 324. This difference in size can ensure that the heating element can be properly accommodated and positioned within the heating part, allowing for efficient heat conduction to the body part 322. In some embodiments, the smaller diameter of the accommodating portion 322c compared to the accommodating portion 324a can help in providing a controlled and directed flow of thermal energy to the protrusion 322a. By way of example, the maximum dimension D8 can be in a range from about 2.5 to 4.5 mm, such as 2.5, 3, 3.3, 3.5, 4, or 4.5 mm, while the maximum dimension D9 can be in a range from about 15 to 25 mm, such as 15, 19.9, 20, or 25 mm.

In FIG. 3E, angles between the protrusions 322a can control heat transfer and the mechanical engagement between the remover portion 320 and the clogging material. An angle R1 can be defined between the protrusions 322a, while an angle R2 can be defined between the two sidewalls of the protrusion 322. Specifically, the angle R1 between the protrusions 322a can influence the ability of the remover portion to engage with and effectively break down the clogging material. In some embodiments, the angle R1 can be in a range from approximately 10 to 30 degrees, such as 10, 15, 18, 20, 25, or 30 degrees. A wider angle R1 can facilitate better heat transfer across a broader area, while a narrower angle can focus the heat more precisely. The angle R2 between the two sidewalls of the protrusions 322 can determine the contact area and the mechanical force applied to the clogging material. In some embodiments, the angle R2 can be greater than the angle R1, depending on the specific operational needs. In some embodiments, the angle R2 can be substantially equal to or smaller than the angle R1, depending on the specific operational needs. By way of example, the angle R2 can also be in a range from approximately 10 to 30 degrees, such as 10, 15, 15.3, 18, 20, 25, or 30 degrees.

As shown in FIG. 3F, in some embodiments, the heating part 324 can be equipped with multiple locking parts 324d to secure it to the support part 310. The locking parts 324d can provide stability to the heating element during the de-clogging process, ensuring that the entire assembly remains properly aligned. In some embodiments, the locking parts 324d can be locking holes. In some embodiments, the locking parts 324d can be positioned at specific distances from one another to provide stability. The distance between two adjacent locking parts 324d can be defined as a distance D10, which can be in a range from approximately 40 to 70 mm, such as 40, 45, 55, 56, 60, 65, or 70 mm. The placement of the locking parts also can allow for easier assembly and disassembly of the thermal remover 300a, making maintenance and repairs more convenient.

As shown in FIG. 3G, the remover portion 320 can have a dimension D11, which extends along the central axis A1 of the accommodating portion 324a. The dimension D11 can represent the overall length of the remover portion 320 along the central axis A1, encompassing both the body part 322 and the heating part 324. In some embodiments, the dimension D11 can be greater than the dimension D1. . By way of example, the dimension D11 can be in a range from about 70 to 150 mm, such as about 70, 80, 90, 100, 110, 112, 120, 130, 140, or 150 mm.

In FIG. 3G, the accommodating portion 322c, which houses components such as the temperature sensor 340, can have a dimension D12 (or depth) extending along the central axis A1 of the accommodating portion 324a. In some embodiments, the dimension D12 can be in a range from approximately 10 to 30 mm, such as 10, 15, 20, 25, or 30 mm. This depth can ensure that the components can be securely positioned within the body part, facilitating accurate temperature monitoring.

In FIG. 3G, the heating part 324 also includes a plurality (e.g., two) of locking parts 324e to fix the heater 330 in place. The locking parts 324e can be aligned with the locking part 324d, which ensures that the heater 330 can be firmly secured to the heating part, thus preventing any movement or misalignment that could affect the efficiency of heat transfer. The locking parts 324e can be configured as locking holes or similar structures that allow the heater to be fixed to the heating part effectively. In some embodiments, the distance between the locking parts 324e can be substantially the same as the dimension D11.

In some embodiments, the thermal remover 300a is versatile in its configuration (see FIGS. 4A-4D), allowing for various adjustments to suit different operational needs. For instance, the number of protrusions 322a on the body part 322 may correspond directly to the number of accommodating portions 322a in the heating part 324, ensuring that each protrusion is effectively heated. However, in other embodiments, the number of protrusions may differ from the number of accommodating portions, allowing for greater flexibility in addressing different clogging scenarios. In some embodiments, the thermal remover 300a can be adapted to different chamber geometries, with protrusions and heating elements configured to ensure thorough cleaning. The shape of the body part 322 and the heating part 324 can be adjusted based on specific chamber dimensions, making the tool versatile for different applications. The thermal remover 300a is therefore an adaptable and efficient solution for removing debris PD from cover 260. By incorporating multiple design features, such as adjustable protrusions, adaptable cross-sectional shapes, and efficient heating mechanisms, the thermal remover 300a can ensures effective debris removal across a range of chamber configurations.

The remover portion 320 can be made from a material that has a high affinity with the debris PD, enabling efficient adhesion and removal of the melted debris. The material of the remover portion 320 can impact the ability of the remover portion 320 to effectively capture and remove the melted metal. The high affinity can ensure that once the debris PD melts, it adheres well to the remover portion 320, allowing for complete extraction from the chamber surface. For example, if the debris PD is tin, the remover portion 320 can be made from brass. In some embodiments, there is an improved adhesion property between brass and tin. When the tin debris melts, it can readily attach to the protrusion 322a of the remover portion 320, enabling effective removal from the cover 260, ensuring that the liquid tin remains in contact with the remover portion 320, facilitating its extraction without leaving residues. The use of brass can not only ensure effective adhesion but also provides durability, allowing the remover portion to withstand repeated use without significant wear.

In some embodiments, several material properties can be considered to ensure the thermal remover's effectiveness and longevity. The remover portion 320 may have good thermal conductivity to efficiently transfer heat from the heating part 324 to the body part 322 and, subsequently, to the debris. For example, the remover portion 320 made from brass can has relatively high thermal conductivity, which allows for rapid and even heating of the debris, leading to effective melting. Therefore, the remover portion 320 can overcome temperature decay by utilizing a material with high thermal conductivity, such as brass, ensuring that the heat generated by the heater 330 can be efficiently transferred all the way to the tip 322b of the protrusion 322a, thus maintaining a consistent temperature across the entire length of the remover portion. Additionally, the remover portion 320 can balance power consumption by optimizing the heat flow, ensuring that the energy input is used efficiently without excess wastage. This approach can not only ensure effective metal de-clogging but also enhance the overall energy efficiency of the system.

By way of example but not limiting the present disclosure, the implementation of the remover portion 320 made from brass can reach a temperature of up to greater than about 250° C., such as about 250, 300, 350, 400, 450, 500, 550, 600, 650, 700, 750, 800, 850, 900, 950, or 1000° C., to melt tin debris. Achieving the phase change of metal clogging, such as tin, may requires a high thermal flux to provide sufficient energy for melting. The remover portion 320 made from brass can have high thermal conductivity, allowing for rapid heat transfer. This can ensure that the energy generated by the heaters is effectively transmitted to the tin clogging, achieving the temperature required for the phase change.

In some embodiments, simulations can be performed to verify that the thermal remover 300a could achieve the temperature conditions to effectively melt the tin clogging while managing thermal dissipation. By way of example but not limiting the present disclosure, boundary conditions for Simulation may include power input and maximum temperature. The power input for the heater can be set at, such as about 850 W, reflecting the operational power during real use. The maximum temperature achievable can be set at about, such as 600° C. This boundary condition can ensure that the system can be capable of reaching the required temperature to successfully melt the tin clogging material.

In some embodiments, the simulation results can evaluate under two scenarios: without tin and with tin present on the tip 322b of the protrusion 322a. Without tin, the temperature at the tip 322b of the protrusion 322a was measured to be 527° C., and the temperature gradient from the heater 330 to the tip 322b of the protrusion 322a was 73° C. With tin, when tin was present at the tip 322b of the protrusion 322a, the temperature dropped to 465° C., and the gradient increased to 135° C. This drop in temperature can be attributed to the heat absorption by the tin as it undergoes a phase change from solid to liquid, and the increased gradient can indicate that a amount of thermal energy was used to overcome the latent heat of fusion, demonstrating the energy required to melt the tin clogging effectively. The simulation results can indicated that the thermal remover 300a can reduce thermal dissipation to maintain optimal performance. Reducing thermal dissipation can include ensuring that as much heat as possible can be directed toward melting the tin clogging rather than being lost to the environment or other components. In some embodiments, the use of brass for the remover portion 320 can help minimize thermal dissipation due to its high thermal conductivity, allowing more of the generated heat to be effectively utilized for melting the tin.

In some embodiments, the remover portion 320 made from brass can possess sufficient mechanical strength to withstand the forces encountered during the cleaning process, providing a good balance between ductility and strength to endure repeated cycles of heating, cooling, and physical contact with the debris without deforming or breaking. Additionally, the remover portion 320 made from brass can be compatible with the heating elements (e.g., heater 330) embedded in the heating part 324 to handle high temperatures without significant expansion or contraction, maintaining stable contact with the heater 330 and ensuring efficient heat transfer. This compatibility can minimize the risk of gaps forming between the heater and the remover portion 320, which could lead to inefficient heating and incomplete debris removal.

In some embodiments, the remover portion 320 can be made from other materials. For example, the remover portion 320 can be made from copper, in which copper can be another metal with high thermal conductivity and improved adhesion properties, making it suitable for applications involving different types of metal debris. The remover portion 320 made from copper can have improved heat transfer capabilities that can lead to even faster melting of debris. In some embodiments, the remover portion 320 can be made from stainless steel, in which stainless steel can offer improved mechanical strength and corrosion resistance. In some embodiments, the remover portion 320 can be made from alloys that can be used to enhance specific properties, such as increasing hardness or improving thermal resistance.

Reference is made to FIGS. 4A to 4D. FIGS. 4A to 4C illustrate thermal removers 300b, 300c, and 300d in accordance with some embodiments of the present disclosure, and FIG. 4D illustrates a thermal remover 300e with an additional moving assembly 350. While FIG. 4A to FIG. 4D illustrate embodiments of thermal removers with different structural configurations than the thermal remover 300a in FIGS. 2A-3H, the present disclosure may repeat reference numerals and/or letters in the various examples. This repetition is for simplicity and clarity and does not dictate a relationship between the various embodiments and/or configurations discussed.

As shown in FIG. 4A, a difference between the embodiment in FIG. 4A and the embodiment in FIGS. 2A-3H is in the arrangement of the accommodating portion 324a of the heating part 324. In the embodiment shown in FIG. 4A, the accommodating portion 324a is located between two protrusions 322a, such that the heater 330 can extend within the heating part 324 and pass between the two protrusions 322a. Specifically, the accommodating portion 324a in FIG. 4A is centrally positioned between two protrusions 322a, and the heater 330 can be inserted in a manner that may ensure more uniform heat distribution to both protrusions 322a, enhancing the ability of the thermal remover 300b to evenly melt and dislodge the clogging material on either side of the protrusions 322a.

As shown in FIG. 4B, a difference between the embodiment in FIG. 4B and the embodiment in FIGS. 2A-3H is in the arrangement of several features, including the positioning of the accommodating portion 322a, the introduction of subdivided protrusions 323, and the addition of trenches 320t along the sidewall 320s of the remover portion 320. Similar to FIG. 4A, the accommodating portion 324a in FIG. 4B is located between two protrusions 322a, such that the heater 330 can extend through the heating part 324 and pass between the two protrusions 322a, ensuring the ability of the thermal remover 300b to evenly melt and dislodge the clogging material on either side of the protrusions 322a.

Additionally, in FIG. 4B, the protrusions 322a can be further subdivided into at least two sub-protrusions 323. This subdivision provides increased surface contact with the clogging material, improving mechanical engagement and heat transfer efficiency. By subdividing the protrusions, the remover portion can achieve more points of contact with the clogging material, thereby providing enhanced grip and making it easier to dislodge and melt the metal debris. The sub-protrusions 323 can effectively increase the surface area for heat transfer, leading to improved melting performance and more efficient clogging removal.

Furthermore, in FIG. 4B, the trenches 320t extend along the sidewall 320s of the remover portion 320. The trenches 320t extend through the opposite edges 320a and 320b of the remover portion 320, and they are arranged such that their extending direction can be parallel to each other but not parallel to the central axis A1 of the accommodating portion 324a. In some embodiments, the trenches 320t can serve as pathways for melted debris to escape from the contact surface, facilitating smoother and more efficient removal of clogging material. By providing these escape routes, the trenches 320t can help ensure that the melted debris does not re-solidify on the sidewall 320s, reducing the likelihood of re-clogging and improving the overall effectiveness of the cleaning process. In some embodiments, the trenches 329t can provides additional mechanical flexibility to the remover portion 320. The trenches 320t can act as stress relief features, allowing the sidewall 320s to expand or contract slightly during heating and cooling cycles without causing deformation or damage to the remover portion 320 to maintain the structural integrity of the remover portion 320 during repeated heating and cooling, thereby extending the operational lifespan of the thermal remover 320.

As shown in FIG. 4C, a difference between the embodiment in FIG. 4B and the embodiment in FIGS. 2A-3H is in the arrangement of several features, including the positioning of the accommodating portion 322a, the addition of trenches 320t along the sidewall 320s of the remover portion 320, a horizontal moving mechanism 352 for enhanced positioning, and a spring assembly 360 for surface conformity. Similar to FIGS. 4A and 4B, the accommodating portion 324a is located between two protrusions 322a, such that the heater 330 can extend through the heating part 324 and pass between the two protrusions 322a, and the trenches 320t can extend along the sidewall 320s of the remover portion 320.

Additionally, in FIG. 4C, the horizontal moving mechanism 352 can be connected to the remover portion 320 and can be configured to move the remover portion 320 toward or away from the cover 230 in a direction perpendicular to the central axis A1 of the accommodating portion 324a. The horizontal moving mechanism 352 can allow for precise control over the position of the remover portion 320 relative to the cover 230. By enabling movement perpendicular to the central axis, the remover portion 320 can be adjusted to maintain contact with the clogging material, ensuring efficient heat transfer and melting. In some embodiments, the horizontal moving mechanism 352 can allow the remover portion 320 to adapt to different clogging conditions, such as varying thicknesses or locations of clogging material. This adaptability ensures that the remover portion can be positioned where it is needed, improving the overall effectiveness of the de-clogging process.

Furthermore, in FIG. 4C, the spring assembly 360 includes a plurality of springs connected between the thermal remover 300d and the horizontal moving mechanism 352, allowing the thermal remover 300d to conform to the surface of the cover 230. Specifically, the spring assembly 360 can provide flexibility to the thermal remover 320, enabling it to adjust and conform to surfaces of varying shapes of the cover 320. This can be useful when dealing with covers that are not flat or have irregular contours. The springs can allow the remover portion 320 to maintain consistent contact with the surface, ensuring efficient heat transfer and effective clogging removal.

As shown in FIG. 4D, the thermal remover 300e can include features shown in FIGS. 2A-4C, such as the accommodating portion 324a positioned between two protrusions 322a, the trenches 320t along the sidewall 320s of the remover portion 320, contributing to the efficient removal of metal clogging and provide structural stability during the cleaning process, and the spring assembly 360 between the thermal remover 300d and the moving mechanism 350. The thermal remover 300e further include the moving assembly 350 for multi-directional movement. The moving assembly 350 can include a horizontal moving mechanism 352, a horizontal moving mechanism 354, and a vertical moving mechanism 356, each providing enhanced movement capabilities.

Specifically, in FIG. 4D, the horizontal moving mechanism 352 can be connected to the remover portion 320 and is configured to move the remover portion 320 toward or away from the cover 230 in a direction perpendicular to the central axis A1 of the accommodating portion 324a. The horizontal moving mechanism 352 can provide precise control over the proximity of the remover portion 320 to the clogging material, ensuring that the appropriate amount of heat and contact pressure can be applied during the cleaning process.

Additionally, in FIG. 4D, The horizontal moving mechanism 354 can be connected between the horizontal moving mechanism 352 and the vertical moving mechanism 356. The horizontal moving mechanism 354 can allow the remover portion 320 to move in a direction that is perpendicular to both the central axis A1 and the movement direction of the horizontal moving mechanism 352. This additional degree of horizontal movement can provide the ability to make lateral adjustments, ensuring that the remover portion 320 can access and clean a broader range of surfaces within the chamber.

Furthermore, in FIG. 4D, the vertical moving mechanism 356 can be connected to the horizontal moving mechanism 354 and can be configured to move the remover portion 320 vertically. The vertical movement can allow the remover portion 320 to be positioned at the appropriate height relative to the cover 230, ensuring that the entire surface can be effectively cleaned. The vertical adjustment capability can be used for accommodating different chamber designs or varying clogging locations. By allowing movement in multiple directions (e.g., two horizontal and one vertical), the thermal remover 300e can access all areas of the chamber, ensuring that no part of the surface can be left untreated. In some embodiments, the multi-directional movement provided by the moving assembly 350 can make the thermal remover 300e adaptable to different chamber designs.

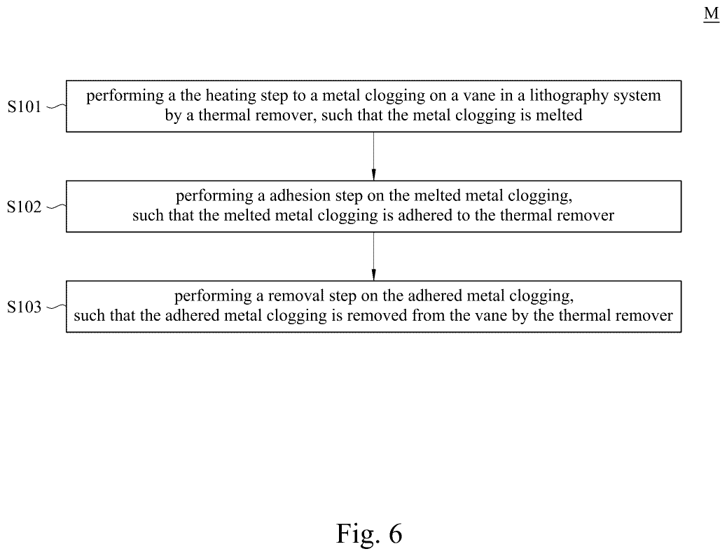

Reference is made to FIGS. 5A-6. FIGS. 5A-5C illustrate schematic views of intermediate stages of using the thermal remover 300a to remove metal clogging from the cover 260 in the lithography system in accordance with some embodiments. The cleaning process of the thermal remover 300a can at least include three steps: heating, adhesion, and removal steps. FIG. 6 illustrates a flowchart of a method of using the thermal remover 300a to remove metal clogging from the cover 260 in the lithography system 100 as illustrated in FIGS. 5A-5C in accordance with some embodiments of the present disclosure. The described method M outlines steps for the movement process. It is to be understood that additional operations may be performed before, during, or after the steps shown in FIGS. 5A-5C, and that some of the described steps may be replaced or omitted in other embodiments. Furthermore, the order of these operations or processes may be interchangeable, providing flexibility depending on specific requirements.

Reference is made to FIGS. 5A and 6. The method M begins at step S101, where a heating step is performed to a metal clogging on a vane in a lithography system by a thermal remover, such that the metal clogging is melted. Specifically, as shown in FIG. 5A, in the heating step, the thermal remover 300a, which includes the heating part 324 and protrusion 322a, can be positioned near the clogging on the surface of the vane 262. The heater 330 within the remover portion can generates heat, which is transferred through the protrusion 322a to the clogged surface. The heating step can soften or melt the metal clogging, which is deposited due to operational processes. The heating can be controlled and focused to achieve a sufficient temperature to melt the clogging without damaging the underlying vane 262 or chamber surface.

Reference is made to FIGS. 5B and 6. The method M proceeds to step S102, where a adhesion step is performed on the melted metal clogging, such that the melted metal clogging is adhered to the thermal remover. As shown in FIG. 5B, once the metal clogging has been adequately softened or melted, the adhesion step begins. The material of the remover portion 320, specifically the protrusion 322a, can have high affinity with the clogging material (e.g., brass is used for removing tin). This affinity can facilitate the melted clogging material to stick or adhere to the protrusion 322a of the thermal remover 300a. During the adhesion step, the shape of the protrusion 322a, which can include triangular or trapezoidal cross-sections, maximizes contact with the clogging, ensuring that the softened material adheres effectively. The combination of the rough inner surface of the protrusion 322a and the consistent heating can provide an enhanced grip, allowing the melted material to migrate from the vane to the thermal knife.

Reference is made to FIGS. 5C and 6. The method M proceeds to step S103, where a removal step is performed on the adhered metal clogging, such that the adhered metal clogging is removed from the vane by the thermal remover. As shown in FIG. 5C, in the removal step, the adhered metal clogging is removed from the vane surface as the thermal remover 300a is gradually withdrawn. The melted material that has adhered to the protrusion 322a begins to flow off due to gravity and further controlled heating, which facilitates the complete detachment of the clogging from the vane. The removal step is performed to be efficient, ensuring that the clogging is thoroughly removed from the surface, leaving only a minimal residue. In some embodiments, the thickness of the remaining clogging can be reduced to below about 6 mm, improving the cleanliness of the vane compared to its initial condition of, such as about 16 to 18 mm.

In some embodiments, the thermal remover 300a can automatically clean the cover 260 in the vessel 210 of the lithography system 100 at regular intervals. By scheduling regular cleaning intervals with the thermal remover 300a, the lithography system 100 can prevent excessive buildup of metal clogging, which helps maintain the functionality of the vessel 210 and avoids interruptions in the lithography process. The cleaning process can reduce maintenance downtime and increase the operational efficiency of the lithography system 100. In addition to the automated cleaning capabilities, the thermal remover 300a can allow for manual operation by maintenance personnel. This manual cleaning capability can provide flexibility, allowing personnel to intervene and perform cleaning operations when needed.

In some embodiments, the thermal remover 300a can be integrated with the control system 60 (see FIGS. 1A and 1C) and the archive database 75 (see FIGS. 1A and 1C). The archive database 75 can continuously collect and monitor data related to the condition of the lithography system. The data collected by the archive database 75 can help in maintaining a historical record of the cleaning operations, which can be used for predictive maintenance and to optimize future cleaning schedules. When the archive database 75 detect that the thermal remover 300a has arrived at a point where cleaning is necessary, it can automatically notify the control system 60. Upon receiving this notification, the control system 60 can take control of the thermal remover 300a and initiate the cleaning process for the cover 230, allowing for a seamless transition between monitoring and action, ensuring that the system is cleaned proactively and efficiently. In some embodiments, the metrology device 40 (see FIGS. 1A and 1C) can be used to detect the status of the cover 230. When the metrology device 40 detects that the status of the cover 230 has reached a threshold requiring cleaning, it can communicate with the control system 60. The control system 60, in turn, can initiate the cleaning operation using the thermal remover 300, providing a real-time and data-driven method for initiating cleaning cycles. By combining real-time monitoring, data analysis, and automation, the thermal remover 300a can ensures that clogging can be effectively managed, leading to improved system reliability and reduced downtime. In some embodiments, the thermal remover 300a can be applied to scrubber and/or vessel backside of EUV scanner clean.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a thermal-based tool (e.g., thermal remover shown in FIGS. 3A-4D) to remove metal clogging from chamber walls of the lithography system. The thermal-based tool can be designed to conform to the shape of the chamber walls, ensuring efficient metal removal without power loss, improving operational efficiency in liquid metal applications, in the lithography systems.

In some embodiments, a method includes providing a thermal remover, wherein the thermal remover comprises a remover portion comprising a plurality of protrusions and a heater extending within the remover portion; positioning the remover portion in contact with a metal clogging deposited on an inner sidewall of a cover within a lithography system, wherein the inner sidewall comprises a plurality of vanes, wherein the protrusions are configured to conform to a shape of the vanes; heating the remover portion with the heater to melt the metal clogging; removing the melted metal clogging from the cover by withdrawing the remover portion. In some embodiments, positioning the remover portion in contact with the metal clogging includes: aligning the protrusions of the thermal remover to fit the vanes within the lithography system. In some embodiments, the remover portion has a non-smooth inner surface to engage with the metal clogging. In some embodiments, heating the remover portion is performed to a temperature in a range from about 400 to 800° C. In some embodiments, heating the remover portion comprises: maintaining a power input to the heater in a range from about 600 to 1000 W. In some embodiments, the thermal remover further comprises a temperature sensor extending within one of the protrusions to monitor a temperature of the one of the protrusions during a removal process on the metal clogging. In some embodiments, the remover portion of the thermal remover is made of a material comprising brass, aluminum, or combinations thereof. In some embodiments, the metal clogging comprises tin. In some embodiments, the method further includes providing a moving mechanism to position the remover portion in contact with the metal clogging. In some embodiments, the moving mechanism comprises a horizontal mechanism and a vertical moving mechanism to position the remover portion in three dimensions relative to the cover.

In some embodiments, a method includes providing a thermal remover comprising a heating part, a plurality of protrusions protruding from the heating part, and a first heater extending within the heating part; inserting the thermal remover into a vessel of an extreme ultraviolet (EUV) radiation source of a lithography system, wherein the EUV radiation source has an inner sidewall in the vessel, the inner sidewall is with a plurality of vanes, and the protrusions of the thermal remover are adapt to match a geometry of the vanes; positioning the thermal remover in contact with a metal clogging on the vanes; heating the thermal remover with the first heater; removing the melted metal clogging by the thermal remover. In some embodiments, the method further includes: adjusting a power of the first heater based on temperature readings obtained from a temperature sensor within the thermal remover. In some embodiments, the protrusions of the thermal remover comprise at least one triangular cross-section to conform to the geometry of the vanes. In some embodiments, the thermal remover comprises a second heater extending within the heating part and in parallel with a lengthwise direction of the first heater. In some embodiments, the protrusions of the thermal remover comprise brass, and the metal clogging comprises tin.

In some embodiments, an apparatus includes a thermal remover, a first heater, and first and second temperature sensors. The thermal remover is made of a material includes brass, aluminum, or combinations thereof. The thermal remover includes a heating part and first and second protrusions. The heating part is operable to deliver heat to a clogging material on vanes in an extreme ultraviolet (EUV) radiation source of a lithography system. The first and second protrusions extend from the heating part and conformal to a shape of the vanes. The first heater extends within the heating part for melting the clogging material. The first temperature sensor extends into the first protrusion. The second temperature sensor extends into the second protrusion, wherein the first and second temperature sensors are operable to monitor a temperature during a removal process on the clogging material. In some embodiments, the first and second protrusions of the thermal remover each have a triangular cross-section. In some embodiments, the first heater is centrally positioned between the first and second protrusions. In some embodiments, the apparatus further includes a second heater extending within the heating part and in parallel with a lengthwise direction of the first heater. In some embodiments, the first protrusion of the thermal remover is aligned with the first heater, and the second protrusion of the thermal remover is aligned with the second heater.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a thermal remover, wherein the thermal remover comprises a remover portion comprising a plurality of protrusions and a heater extending within the remover portion;
positioning the remover portion in contact with a metal clogging deposited on an inner sidewall of a cover within a lithography system, wherein the inner sidewall comprises a plurality of vanes, wherein the protrusions are configured to conform to a shape of the vanes;
heating the remover portion with the heater to melt the metal clogging; and
removing the melted metal clogging from the cover by withdrawing the remover portion.

2. The method of claim 1, wherein positioning the remover portion in contact with the metal clogging comprises:
aligning the protrusions of the thermal remover to fit the vanes within the lithography system.

3. The method of claim 1, wherein the remover portion has a non-smooth inner surface to engage with the metal clogging.

4. The method of claim 1, wherein heating the remover portion is performed to a temperature in a range from about 400 to 800° C.

5. The method of claim 1, wherein heating the remover portion comprises: maintaining a power input to the heater in a range from about 600 to 1000 W.

6. The method of claim 1, wherein the thermal remover further comprises a temperature sensor extending within one of the protrusions to monitor a temperature of the one of the protrusions during a removal process on the metal clogging.

7. The method of claim 1, wherein the remover portion of the thermal remover is made of a material comprising brass, aluminum, or combinations thereof.

8. The method of claim 1, wherein the metal clogging comprises tin.

9. The method of claim 1, further comprising:
providing a moving mechanism to position the remover portion in contact with the metal clogging.

10. The method of claim 9, wherein the moving mechanism comprises a horizontal mechanism and a vertical moving mechanism to position the remover portion in three dimensions relative to the cover.

11. A method, comprising:
providing a thermal remover comprising a heating part, a plurality of protrusions protruding from the heating part, and a first heater extending within the heating part;
inserting the thermal remover into a vessel of an extreme ultraviolet (EUV) radiation source of a lithography system, wherein the EUV radiation source has an inner sidewall in the vessel, the inner sidewall is with a plurality of vanes, and the protrusions of the thermal remover are adapt to match a geometry of the vanes;
positioning the thermal remover in contact with a metal clogging on the vanes;
heating the thermal remover with the first heater; and
removing the melted metal clogging by the thermal remover.

12. The method of claim 11, further comprising:
adjusting a power of the first heater based on temperature readings obtained from a temperature sensor within the thermal remover.

13. The method of claim 11, wherein the protrusions of the thermal remover comprise at least one triangular cross-section to conform to the geometry of the vanes.

14. The method of claim 11, wherein the thermal remover comprises a second heater extending within the heating part and in parallel with a lengthwise direction of the first heater.

15. The method of claim 11, wherein the protrusions of the thermal remover comprise brass, and the metal clogging comprises tin.

16. An apparatus, comprising:
a thermal remover, the thermal remover being made of a material comprising brass, aluminum, or combinations thereof, the thermal remover comprising:
a heating part operable to deliver heat to a clogging material on vanes in an extreme ultraviolet (EUV) radiation source of a lithography system; and
first and second protrusions extending from the heating part and conformal to a shape of the vanes;
a first heater extending within the heating part for melting the clogging material;
a first temperature sensor extending into the first protrusion; and
a second temperature sensor extending into the second protrusion, wherein the first and second temperature sensors are operable to monitor a temperature during a removal process on the clogging material.

17. The apparatus of claim 16, wherein the first and second protrusions of the thermal remover each have a triangular cross-section.

18. The apparatus of claim 16, wherein the first heater is centrally positioned between the first and second protrusions.

19. The apparatus of claim 16, further comprising:
a second heater extending within the heating part and in parallel with a lengthwise direction of the first heater.

20. The apparatus of claim 19, wherein the first protrusion of the thermal remover is aligned with the first heater, and the second protrusion of the thermal remover is aligned with the second heater.
